(19) United States
(12) Patent Application Publication
(10) Pub. No.: US 2011/0234507 A1
(43) Pub. Date: Sep. 29, 2011

(54) INTEGRATED TOUCH PANEL AND MANUFACTURING METHOD THEREOF

(75) Inventors: SHIH-LIANG CHOU, TAO-YUAN (TW); HSUEH-CHIH CHIANG, TAO-YUAN (TW); CHIEN-MIN WENG, TAO-YUAN (TW); TZU-WEN CHU, TAO-YUAN (TW); FU-JEN WANG, TAO-YUAN (TW); I-WEN LEE, CHUNG LI CITY (TW); HSING-YEH CHEN, CHUNG LI CITY (TW)

(73) Assignees: APPLIED VACUUM COATING TECHNOLOGIES CO., LTD., TAO-YUAN (TW); AVCT OPTICAL ELECTRONIC CO., LTD., CHUNG LI CITY (TW)

(21) Appl. No.: 12/847,327

(22) Filed: Jul. 30, 2010

(30) Foreign Application Priority Data
Mar. 26, 2010 (TW) 099109075

(51) Int. Cl. G06F 3/041; C23C 14/34

(52) U.S. Cl. 345/173; 204/192.15

(57) ABSTRACT

The present invention provides an integrated touch panel comprising a transparent substrate, one of an icon or artwork layer, a first layer of optical film, and a first sensing layer. The icon layer or artwork layer is coated on the periphery of one side face of the transparent substrate, and the inner periphery of the icon layer or artwork layer is not perpendicular to the adjacent line of the transparent substrate. The first layer of optical film is stacked on icon layer or artwork layer and the areas on the transparent substrate uncovered with icon layer. The first sensing layer is stacked on the first layer of optical film by sputtering. The interchangeability is included in the patent claim of the present invention. As icon layer or artwork layer is not perpendicular to the transparent substrate, the subsequent cladding of the structures may be completed by sputtering or other methods.

### CROSS-REFERENCE TO RELATED APPLICATIONS

This non-provisional application claims priority under 35 U.S.C. §119(a) on Patent Application No(s). 099109075 filed in Taiwan, R.O.C. on Mar. 26, 2010, the entire contents of which are hereby incorporated by reference.

### BACKGROUND OF THE INVENTION

1. Field of the Invention

The present invention is related to the touch panel technology, specifically in the invention of an integrated touch panel of which production process is simplified, panel strength is intensified, and yield rate is increased.

2. Description of the Related Art

There are some common types of touch panels; i.e. the resistive panel, capacitive panel, surface acoustic wave panel, optical (infrared) panel etc. Among these, the most commonly used are the resistive panels, followed by the capacitive panels. The advantages of the capacitive panels are waterproofing and scratch-proofing, and they have high light transmittance and broad temperature range. Therefore, the panels come at a high price. With the advancement of technology, however, the capacitive panels are beginning to gain a share in the market of small monitors.

The outermost surface of the conventional touch panel, which comes to contact with the environment, is usually made of a chemical-tempered cover glass substrate. This outermost cover substrate is then laminated to the sensing layer, which uses indium tin oxide (ITO) as its conductance. Integrating this combination with the display panel (i.e. the back light module) produces a complete touch screen. In the past, the cover glass substrate and the sensing layer, as described above, are laminated with optically clear adhesive (OCA). Other than that, an additional black icon or artwork layer is printed on the edges of the cover glass substrate to shield the circuits. The conventional icon layer is printed on the cover glass substrate perpendicularly and this will usually cause unsatisfactory results when laminating the substrate to the sensing layer; incomplete or uneven cladding may occur. Many times, the uneven slots produced during the etching of sensing circuits on the ITO sensing layers will compromise the quality of the images on the display and reduce its yield rate.

In order to improve the poor outcome caused by the conventional OCA lamination process, the inventor invented an integrated touch panel which uses low temperature sputtering method to stack the films instead of OCA lamination. This will effectively reduce the thickness of the touch panel and thus increase the light transmittance efficiency. Furthermore, stacking optical film on the sensing layer with sputtering method has lesser problems of uneven slots caused by circuit etching and thus the quality of the images on the display is improved. Moreover, the placement of the icon layer is different from that in the conventional device and this will improve the cladding of the subsequent coatings remarkably and will get rid of the problems of uneven coatings all together. The overall strength of the panel is also improved greatly.

### SUMMARY OF THE INVENTION

In view of the abovementioned problems, the purpose of the present invention is to coat on one of an icon or artwork layer on the periphery of one side face of the transparent substrate, also the inner periphery of the icon or artwork layer is not perpendicular to the adjacent line of the transparent substrate. Sputtering method is then used to stack layers of optical films or sensing layers on the above. As the icon layer or artwork layer is not placed perpendicularly, complete cladding of the optical films or sensing layers can be done and thus the yield rate of the device increased.

In order to achieve the above objectives, an integrated touch panel is introduced in the present invention. It consists of one transparent substrate, one of an icon layer or artwork layer, the first layer of the optical film, and the first sensing layer. The icon layer or artwork layer is coated on the periphery of one side face of the transparent substrate and its inner periphery is not perpendicular to the adjacent line of the transparent substrate. The first layer of optical film is stacked on such icon layer and the areas on the transparent substrate which are not coated with the icon layer. The first sensing layer is stacked on the first optical film via sputtering method.

The transparent substrate used in the present invention may either be made of glass or polymer plastics. One passivation film may be included in the structure and is stacked on the first sensing layer.

The integrated touch panel may further comprise a second layer of optical film stacked on the first sensing layer and a passivation film may or may not be stacked on the optical film. The first isolation layer may be stacked on the second layer of optical film, and a third layer of optical film may be stacked on such isolation layer. A second sensing layer may be stacked on the third optical film, and a passivation film may be subsequently stacked on such sensing layer. The invention may further comprise a layer of shield stacked on the second sensing layer, and a passivation film stacked on the shield.

The present invention further comprises the first isolation layer stacked on the second optical film. The isolation layer may then be stacked by a second sensing layer followed by a passivation film. Alternatively, it may consist of a second sensing layer stacked on the first isolation layer followed by a second isolation layer. A shield may then be stacked on the second isolation layer, followed by a passivation film.

In order to achieve the above objectives, an integrated touch panel is introduced in the present invention. It consists of one transparent substrate and one of an icon layer or artwork layer coated on the periphery of one side face of the transparent substrate and its inner periphery is not perpendicular to the adjacent line of the transparent substrate. It consists of the first sensing layer which is stacked on the abovementioned icon layer and the areas on the transparent substrate which are not coated with the icon layer or artwork layer. It consists of the first layer of optical film stacked on the above sensing layer via sputtering method. Its structure may further comprise a passivation film stacked on the above first optical film. Alternatively, it may further comprise the first isolation layer stacked on the above optical film followed by a second sensing layer. A second layer of the optical film may be stacked on such second sensing layer followed by a layer of passivation film. Alternatively, it may further consist of a second isolation layer stacked on the second layer of optical film followed by a layer of shield. A passivation film may then be stacked on the shield.

In order to achieve the above objectives, an integrated touch panel is introduced in the present invention. It consists of one transparent substrate and one of an icon layer or artwork layer coated on periphery of one side face of the transparent substrate and its inner periphery is not perpendicular to the adjacent line of the transparent substrate. The first layer of optical film is stacked on the abovementioned icon layer and the areas on the transparent substrate which are not coated with the icon layer. Other than that, it consists of the first sensing layer which is stacked on the above optical film layer via sputtering method. A second layer of optical film is stacked on the first sensing layer and the first isolation layer is stacked on such optical film. A third layer of optical film is stacked on the first isolation layer. A second sensing layer is then stacked on the third layer of optical film via sputtering method. A fourth layer of optical film is stacked on the above second sensing layer followed by a passivation film.

In order to achieve the above objectives, an integrated touch panel is introduced in the present invention. It consists of one transparent substrate and one of an icon layer or artwork layer which is coated on the periphery of one side face of the transparent substrate and its inner periphery is not perpendicular to the adjacent line of the transparent substrate. It also consists of the first layer of optical film which is coated on the abovementioned icon layer or artwork layer and the areas on the transparent substrate which are not coated with icon layer or artwork layer. Other than that, it consists of the first sensing layer which is stacked on the above optical film layer via sputtering method. A second layer of optical film is stacked on the first sensing layer and the first isolation layer is stacked on such optical film. A third layer of optical film is stacked on the first isolation layer. A second sensing layer is then stacked on the third layer of optical film via sputtering method. A fourth layer of optical film is stacked on the above second sensing layer followed by a layer of shield. A passivation film is then stacked on the shield.

The other purpose of the present invention is to propose a production method for the abovementioned integrated touch panel. The temperature of the entire production process has to be controlled below 200° C. in order to greatly enhance the strength and stability of the touch panel. The production steps include cutting the transparent substrate into a few pieces and coating an icon layer on the periphery of each transparent substrate. The inner periphery of each icon layer or artwork layer is not perpendicular to the adjacent line of such transparent substrate. A sensing layer is coated on each icon layer or artwork layer and the areas on the transparent substrate which are not coated with icon layer or artwork layer via sputtering method. However, prior to and/or after the stacking of the sensing layer, at least one layer of optical film may be formed and placed on one side face or two side face of the sensing layer.

One of the advantages of the present invention is that instead of using the conventional way of laminating the transparent substrate and sensing layer with optically clear adhesive, the inner periphery of the icon layer or artwork layer is arranged not perpendicular to the adjacent line of the transparent substrate so that a complete cladding of the optical film or sensing layer can be done via sputtering method. The yield of the structure is thus raised. At the same time, one layer or two layers of optical film are covered on the top and/or bottom surface of each sensing layer. This addition will cover up the metal slots caused by circuit etching preventing them from reducing the resolution and impairing the visual quality of the touch panel.

### BRIEF DESCRIPTION OF THE DRAWINGS

FIG. 1 is a cross section view in accordance with the first embodiment of the present invention;

FIG. 2 is a cross section view of an extended embodiment in accordance with the first embodiment of the present invention (Ext. 1.1);

FIG. 3 is a cross section view in accordance with an extended embodiment of the first embodiment of the present invention (Ext. 1.2);

FIG. 4 is a cross section view in accordance with an extended embodiment of the first embodiment of the present invention (Ext. 1.3);

FIG. 5 is a cross section view in accordance with an extended embodiment of the first embodiment of the present invention (Ext. 1.4);

FIG. 6 is a cross section view in accordance with an extended embodiment of the first embodiment of the present invention (Ext. 1.5);

FIG. 7 is a cross section view in accordance with an extended embodiment of the first embodiment of the present invention (Ext. 1.6);

FIG. 8 is a cross section view in accordance with an extended embodiment of the first embodiment of the present invention (Ext. 1.7);

FIG. 9 is a cross section view in accordance with an extended embodiment of the first embodiment of the present invention (Ext. 1.8);

FIG. 10 is a cross section view of an extended embodiment in accordance with the first embodiment of the present invention (Ext. 1.9);

FIG. 11 is a cross section view of an extended embodiment in accordance with the first embodiment of the present invention (Ext. 1.10);

FIG. 12 is a cross section view of an extended embodiment in accordance with the first embodiment of the present invention (Ext. 1.11);

FIG. 13 is a cross section view in accordance with the second embodiment of the present invention;

FIG. 14 is a cross section view of an extended embodiment in accordance with the second embodiment of the present invention (Ext. 2.1);

FIG. 15 is a cross section view of an extended embodiment in accordance with the second embodiment of the present invention (Ext. 2.2);

FIG. 16 is a cross section view of an extended embodiment in accordance with the second embodiment of the present invention (Ext. 2.3);

FIG. 17 is a cross section view of an extended embodiment in accordance with the second embodiment of the present Invention (Ext. 2.4);

FIG. 18 is a cross section view of an extended embodiment in accordance with the second embodiment of the present invention (Ext. 2.5);

FIG. 19 is a cross section view of the third embodiment in accordance with the present invention;

FIG. 20 is a cross section view in accordance with the fourth embodiment of the present invention;

FIG. 21 is a flow chart of the production process in accordance with the preferred embodiment of the present invention (PE 1); and

FIG. 22 is a flow chart of the production process in accordance with the preferred embodiment of the present invention (PE 2).

### DETAILED DESCRIPTION OF THE PREFERRED EMBODIMENTS

The descriptions of the drawings are given below so that the certification committee will have a clear idea of the subject matter of the present invention. Please refer to the drawings and their respective descriptions.

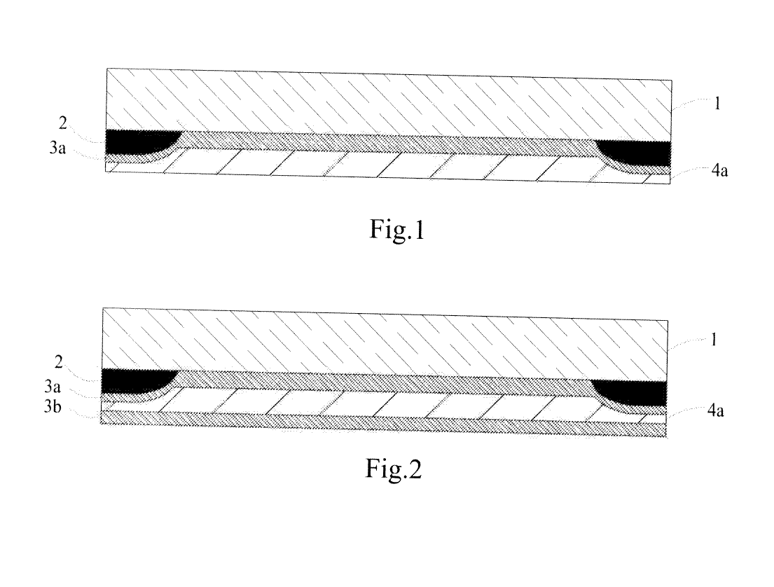

Please refer to the first drawing (FIG. 1). FIG. 1 shows the cross section view of the first embodiment of the present invention. As shown in the drawing, the embodiment is the structure of an integrated touch panel. Combining a display panel (not shown in the drawing) with it will create a complete panel. This integrated touch panel is made up of a transparent substrate 1, an icon layer or an artwork layer 2, a first layer of optical film 3a, and a first sensing layer 4a.

The transparent substrate 1 is the outermost surface of the touch panel that directly comes to contact with the environment. Therefore, it is strengthened to protect it from scratch and other damages. The transparent substrate 1 may either be made from glass or polymer plastic. If glass is used as its material, the glass is first cut into several small pieces where the thickness of each is about 0.5˜1.8 mm. These little pieces are then chemically-tempered by dipping them in potassium nitrate solution or other chemical solutions.

The icon layer or artwork layer 2 mainly functions as a shield to cover up the signal conducting wires at the edges of the touch panel. To do that, ink prints of about 2-15 μm thick are coated on periphery of one side face of the transparent substrate 1. Also, the inner periphery of the icon layer is not perpendicular to the adjacent line of the transparent substrate 1 so that the cladding of the subsequent structures can be complete. In order to control the screen printings so that they are formed at a non-perpendicular angle, the below parameters are required: ink with a viscosity of 10˜300 dPa·s, the screen conditioned at 50˜400 mesh tetron screen, and the tension at minimun 15N.

Prior to stacking the first sensing layer 4a, the first layer of optical film 3a should be stacked on the icon layer or artwork layer 2 and those areas on the transparent substrate 1 which are not coated with the icon layer or artwork layer 2. This would prevent the formation of uneven metal slots on the sensing layer 4a caused by circuit etching and thus minimize the impairment of visual quality. The embodiment of the first layer of optical film 3a can be achieved through sputtering, spraying, or coating methods and its thickness is limited to within 200 nm.

As mentioned above, the first sensing layer 4a is then stacked on the first layer of optical film 3a via sputtering method. One example of this is the ITO transparent conductive film with a thickness of 10-100 nm. This can be done using vacuum DC and RF magnetron sputtering deposition technique. Otherwise, methods like layer-by-layer sputtering, spray pyrolysis, pulsed laser deposition, arc discharge ion plating, reactive evaporation, ion beam sputtering, or chemical vapor deposition (CVD) etc. can be used.

Please refer to the second drawing (FIG. 2). FIG. 2 shows the cross section view of an extended embodiment of the first embodiment (Ext. 1.1) of the present invention. A second layer of optical film 3b is added on the first sensing layer 4a in this embodiment. The purpose, production process, and thickness of this layer of optical film are similar to that of the abovementioned optical film 3a and as such, are not repeated here.

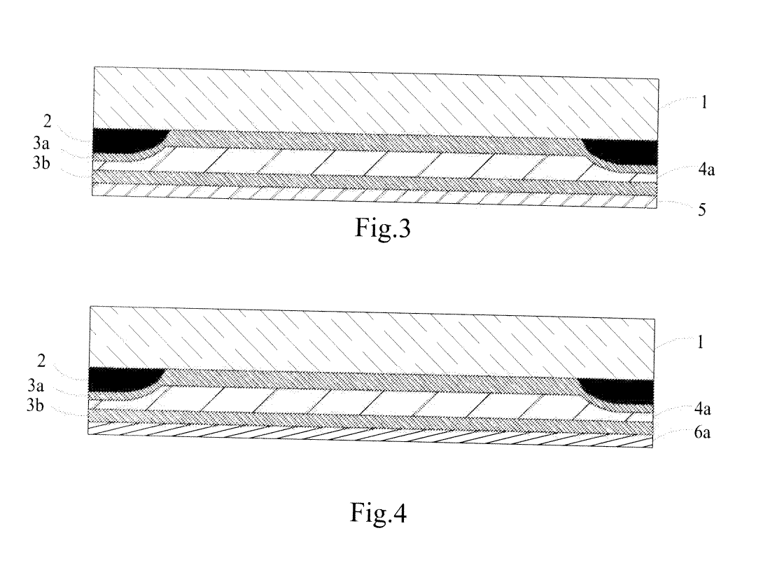

Please refer to the third drawing (FIG. 3). FIG. 3 shows the cross section of an extended embodiment of the first embodiment (Ext. 1.2) of the present invention. The structural difference between this embodiment and the previous (Ext. 1.1) is that the current embodiment comes with a passivation film 5 stacked on the second layer of optical film 3b; the objective of which is to protect the integrated touch panel from scratch and damages when combining it with the display panel. Printing, spraying, or coating methods may be used to produce it and the thickness of the passivation film 5 is maintained below 20 μm.

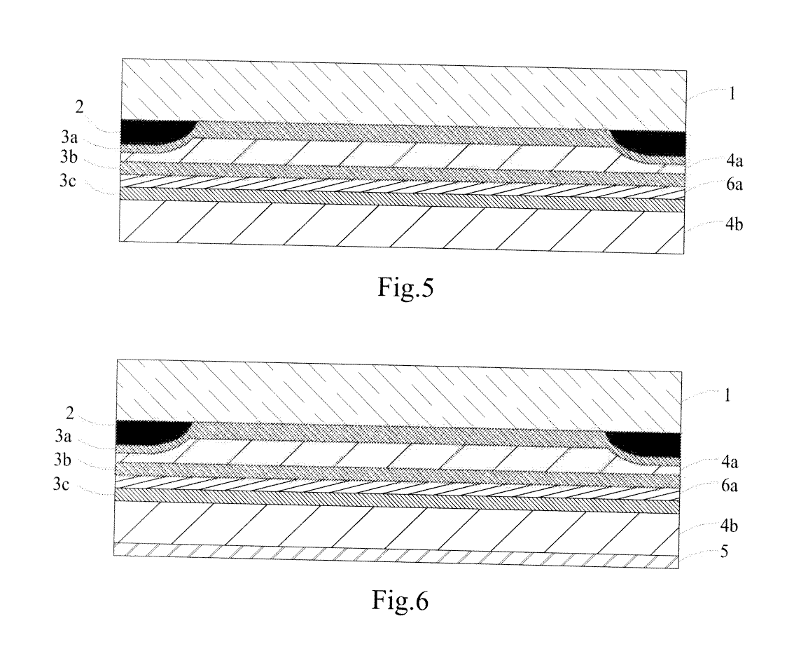

Please refer to the fourth drawing (FIG. 4). FIG. 4 shows the cross section view of an extended embodiment of the first embodiment (Ext. 1.3) of the present invention. The difference between this embodiment and the first extended embodiment (Ext. 1.1) is that the current embodiment comes with an isolation layer 6a stacked on the first sensing layer 4a. This first layer of isolation 6a insulates the first sensing layer 4a from the subsequent sensing layer 4b as shown in FIG. 5. Whenever the panel is touched, capacitance effect is produced in both sensing layers 4a, 4b so as to generate inductive signals. These signals are transmitted to a processor and calculation of the induction-spot is carried out. This is how the touch screen works.

Please refer to the fifth drawing (FIG. 5). FIG. 5 shows the cross section view of an extended embodiment of the first embodiment (Ext. 1.4) of the present invention. The structural difference between this embodiment and the previous extended embodiment (Ext. 1. 3) is that the current embodiment comes with a third layer of optical film 3c stacked on the first isolation layer 6a which is covering the second sensing layer 4b mentioned above. The purpose of the current third layer of optical film 3c is similar to that of the first layer 3a and second layer 3b of optical films and as such, is not repeated here.

Please refer to the sixth drawing (FIG. 6). FIG. 6 shows the cross section of an extended embodiment of the first embodiment (Ext. 1.5) of the present invention. The structural difference between this embodiment and the previous extended embodiment (Ext. 1.4) is that the current embodiment comes with a layer of passivation film 5 stacked on the second sensing layer 4b. This passivation film is similar to that mentioned above, that is to protect the integrated touch panel from scratch and damages when combining it with the display panel. Printing, spraying, or coating methods may be used in its production process and the thickness of the passivation film 5 is maintained below 20 μm.

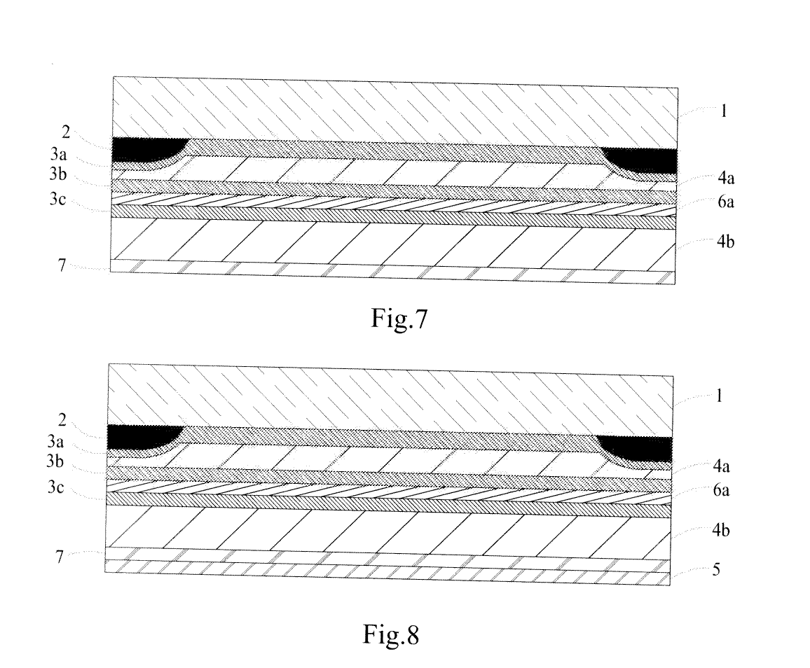

Please refer to the seventh drawing (FIG. 7). FIG. 7 shows the cross section of an extended embodiment of the first embodiment (Ext. 1.6) of the present invention. The structural difference between this embodiment and the abovementioned extended embodiment (Ext. 1.4) is that the current embodiment comes with a layer of shield 7 stacked on the second sensing layer 4b. The purpose of the shield is to block electromagnetic signal interference from other sources. Sputtering method is used in the production process and the thickness is controlled within 10-100 nm.

Please refer to the eighth drawing (FIG. 8). FIG. 8 shows the cross section view of an extended embodiment of the first embodiment (Ext. 1.7) of the present invention. The structural difference between this embodiment and the previous extended embodiment (Ext. 1.6) is that the current embodiment comes with a layer of passivation film 5 stacked on the layer of shield 7. The purpose of this passivation film 5 is similar to that mentioned above, that is to protect the integrated touch panel from scratch and damages when combining it with the display panel. Printing, spraying, or coating methods may be used in its production process and the thickness of the passivation film 5 is maintained below 20 μm.

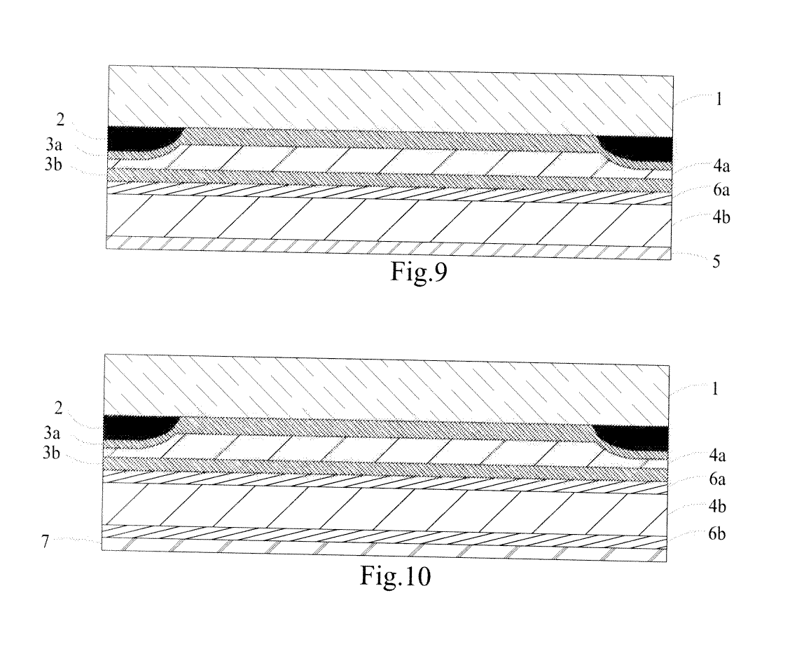

Please refer to the ninth drawing (FIG. 9). FIG. 9 shows the cross section view of an extended embodiment of the first embodiment (Ext. 1.8) of the present invention. The structural difference between this embodiment and the abovementioned extended embodiment (Ext. 1.3) is that the current embodiment comes with a second sensing layer 4b stacked on the first layer of isolation 6a and a layer of passivation film 5 is in turn stacked on such sensing layer 4b. The purpose of the passivation film 5 is similar to that mentioned above and as such, is not repeated here.

Please refer to the tenth drawing (FIG. 10). FIG. 10 shows the cross section view of an extended embodiment of the first embodiment (Ext. 1.9) of the present invention. The structural difference between this embodiment and the above-mentioned extended embodiment (Ext. 1.3) is that the current embodiment comes with a second sensing layer 4b stacked on the first layer of isolation 6a and a second layer of isolation is in turn stacked on the sensing layer 4b. A layer of shield 7 is stacked on the second layer of isolation 6b which now insulates the shield 7 from the second sensing layer 4b. The layer of shield 7 is a transparent protective layer which blocks all noise and is produced via sputtering method. Its thickness is controlled within 10-100 nm.

Please refer to the eleventh drawing (FIG. 11). FIG. 11 shows the cross section view of an extended embodiment of the first embodiment (Ext. 1.10) of the present invention. The structural difference between this embodiment and the previous extended embodiment (Ext. 1.9) is that the current embodiment comes with a layer of passivation film 5 stacked on the layer of shield 7. The purpose of the passivation film 5 is similar to that mentioned above and as such, is not repeated here.

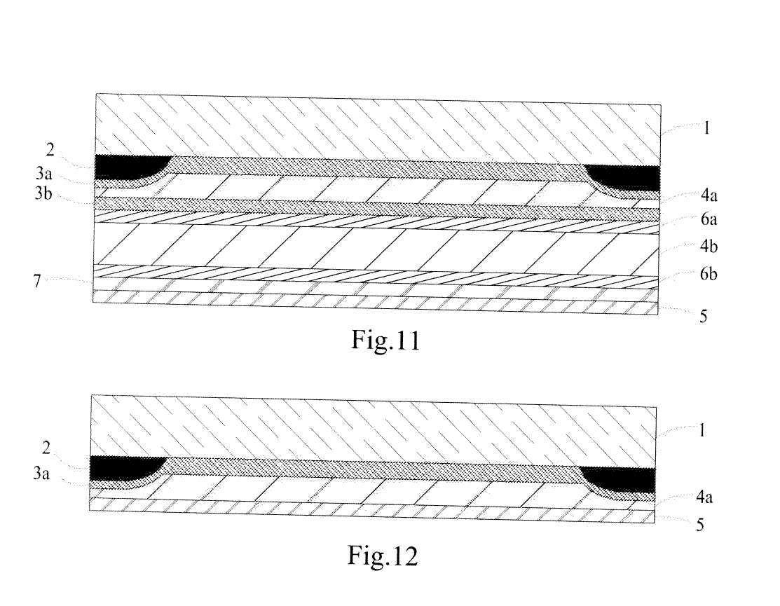

Please refer to the twelfth drawing (FIG. 12). FIG. 12 shows the cross section view of an extended embodiment of the first embodiment (Ext. 1.11) of the present invention. The structural difference between this embodiment and the first embodiment is that the current embodiment comes with a layer of passivation film 5 stacked on the first sensing layer 4a. The purpose of the passivation film 5 is similar to that mentioned above and as such, is not repeated here.

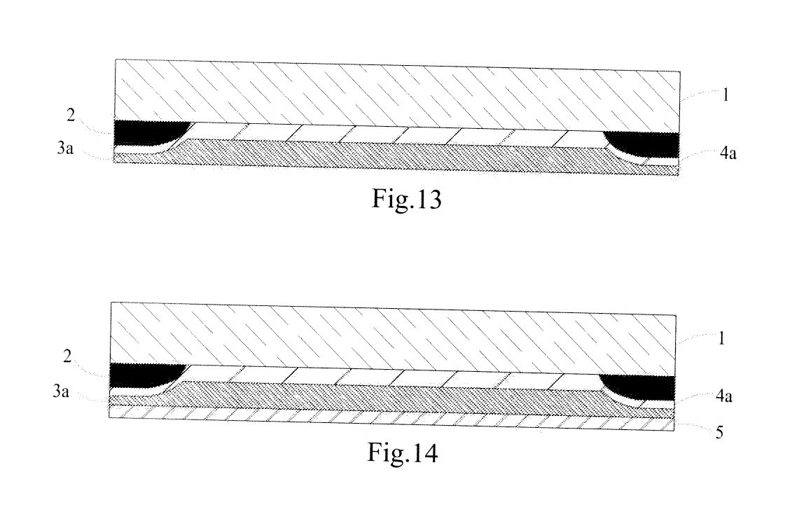

Please refer to the thirteenth drawing (FIG. 13). FIG. 13 shows the cross section view of the second embodiment of the present invention. The second embodiment is generally similar to the first embodiment except that the first sensing layer 4a and the first layer of optical film 3a in both embodiments are swapped places. The purpose of each layer in the structure and the production process are similar to the first embodiment and as such, are not repeated here.

Please refer to the fourteenth drawing (FIG. 14). FIG. 14 shows the cross section view of an extended embodiment of the second embodiment (Ext. 2.1) of the present invention. The structural difference between this embodiment and the second embodiment is that the current embodiment comes with a layer of passivation film 5 stacked on the first layer of optical film 3a. The purpose of this passivation film 5 is similar to that mentioned above, that is to protect the integrated touch panel from scratch and damages when combining it with the display panel. Printing, spraying, or coating methods may be used in its production process and the thickness of the passivation film 5 is maintained below 20 μm.

Please refer to the fifteenth drawing (FIG. 15). FIG. 15 shows the cross section of an extended embodiment of the second embodiment (Ext. 2.2) of the present invention. The structural difference between this embodiment and the second embodiment is that the current embodiment comes with a layer of isolation 6a stacked on the first layer of optical film 3a. It also comprises a second sensing layer 4b stacked on the first layer of isolation 6a and a second layer of optical film 3b stacked on the second sensing layer 4b. The isolation layer 6a is placed between the second sensing layer 4b and the first sensing layer 4a. Whenever the panel is touched, capacitance effect is produced in both sensing layers 4a, 4b so as to generate inductive signals. These signals are transmitted to a processor and calculation of the induction-spot is carried out. This is how the touch screen works. Other than that, the purpose of the first layer of optical film 4a and the second layer of optical film 3b is to prevent the formation of uneven metal slots caused by circuit etching and thus minimize the impairment of visual quality. The quality of the images can then be enhanced.

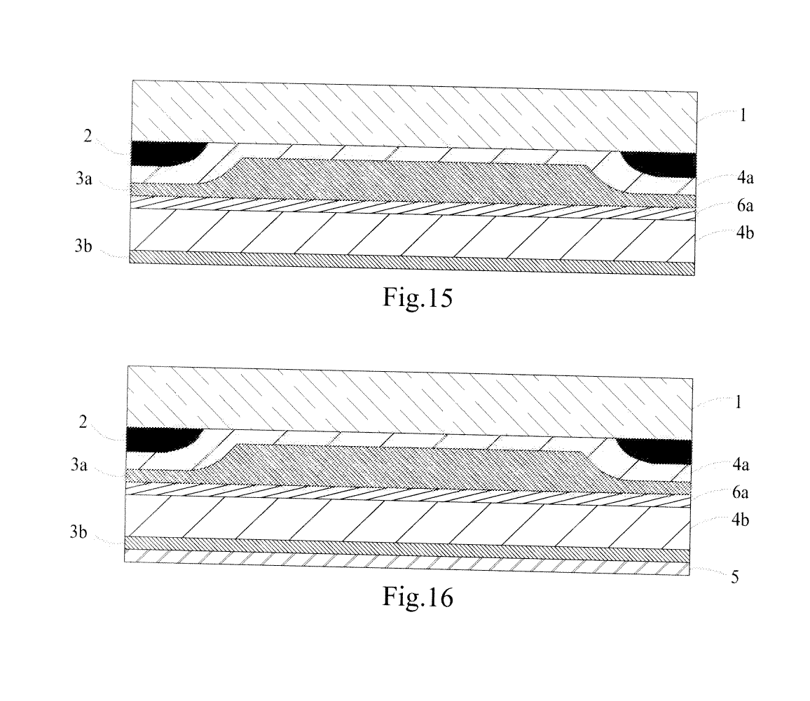

Please refer to the sixteenth drawing (FIG. 16). FIG. 16 shows the cross section of an extended embodiment of the second embodiment (Ext. 2.3) of the present invention. The structural difference between this embodiment and the second extended embodiment (Ext. 2.2) is that the current embodiment comes with a passivation film 5 stacked on the second layer of optical film 3b. The purpose of the passivation film 5 is similar to that mentioned above and as such, is not repeated here.

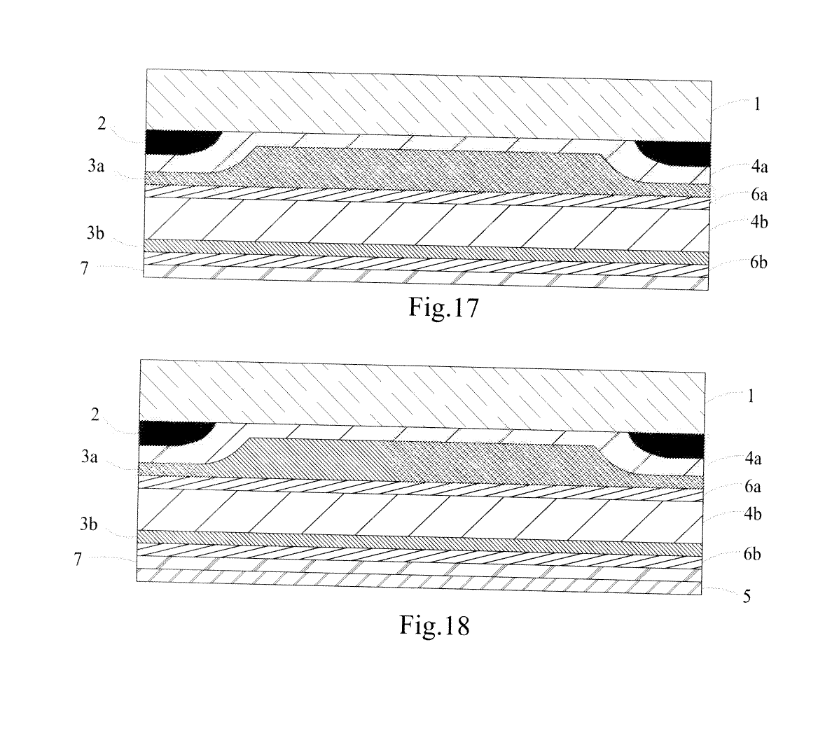

Please refer to the seventeenth drawing (FIG. 17). FIG. 17 shows the cross section view of an extended embodiment of the second embodiment (Ext. 2.4) of the present invention. The structural difference between this embodiment and the second extended embodiment (Ext. 2.2) is that the current embodiment comes with a second layer of isolation 6b stacked on the second layer of optical film 3b. A layer of shield 7 is also stacked on the second layer of isolation 6b which now insulates the second sensing layer 4b from the shield 7. The layer of shield 7 is a transparent protective layer which blocks all noise and is produced via sputtering method. Its thickness is controlled within 10-100 nm.

Please refer to the eighteenth drawing (FIG. 18). FIG. 18 shows the cross section view of an extended embodiment of the second embodiment (Ext. 2.5) of the present invention. The structural difference between this embodiment and the second extended embodiment (Ext. 2.4) is that the current embodiment comes with a passivation film 5 stacked on a layer of shield 7. The purpose of the passivation film 5 is similar to that mentioned above and as such, is not repeated here.

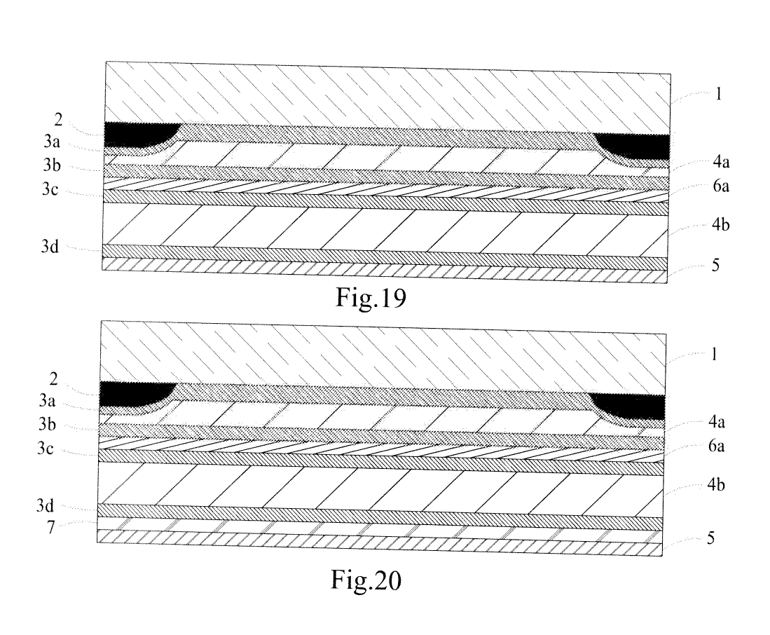

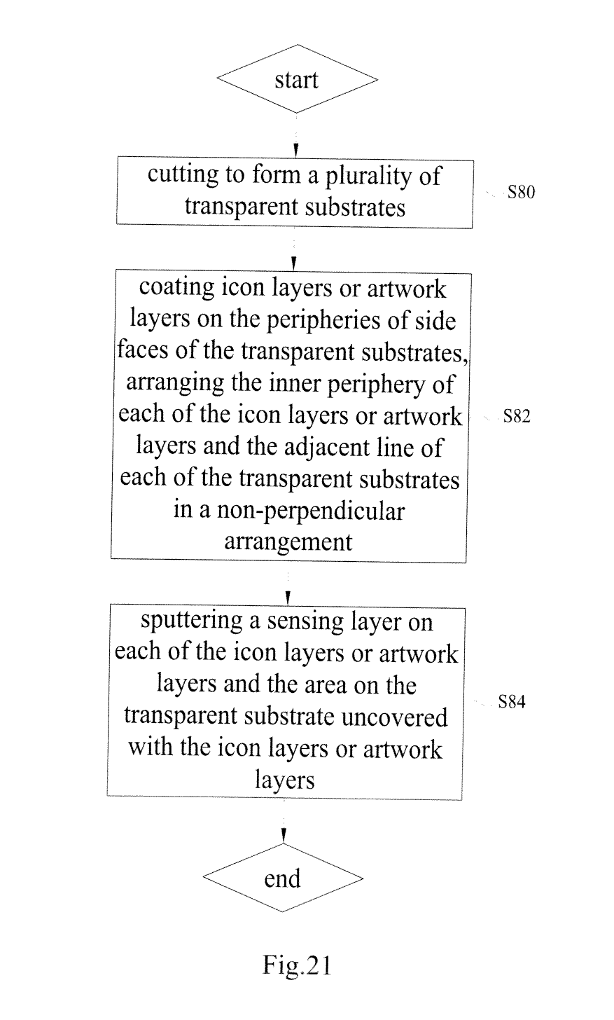

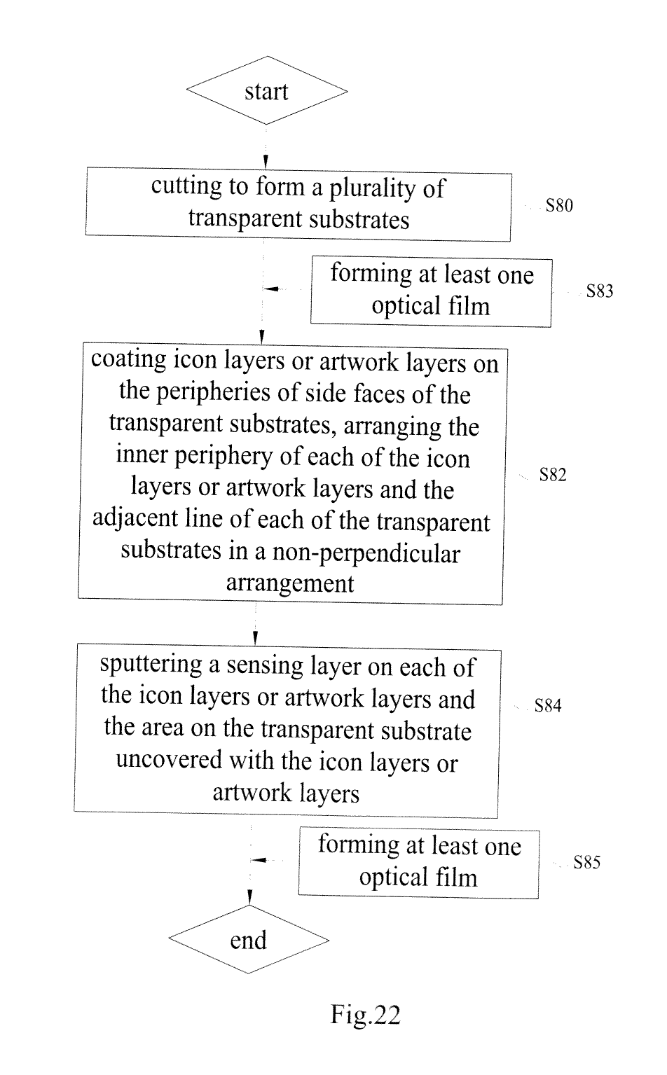

Please refer to the nineteenth drawing (FIG. 19). FIG. 19 shows the cross section view of the third embodiment of the present invention. As shown in the drawing, the embodiment is the structure of an integrated touch panel combined with a display panel (not shown in the drawing) forming a complete panel. The integrated touch panel is made up of one transparent substrate 1 and one icon layer 2 coated on the periphery of one side face of the transparent substrate 1. The inner edge of the icon layer or artwork layer 2 is not perpendicular to the adjacent line of the transparent substrate 1. It also consists of the first layer of optical film 3a which is stacked on the abovementioned icon layer or artwork layer 2 and the areas on the transparent substrate 1 which are not coated with icon layer or artwork layer 2. Other than that, it consists of the first sensing layer 4a which is stacked on the above optical film 3a via sputtering method. A second layer of optical film 3b is stacked on the first sensing layer 4b and the first isolation layer 6a is stacked on the second layer of optical film 3b. A third layer of optical film 3c is stacked on the first isolation layer 6a and a second sensing layer 4b is stacked on the third layer of optical film 3c via sputtering method. A fourth layer of optical film 3d is stacked on the second sensing layer 4b and a layer of passivation film 5 is stacked on the fourth layer of optical film 3d mentioned above. There are sensing layers in this embodiment and the top and bottom of both layers are covered with optical film, meaning the top and bottom of the first sensing layer 4a is covered with the first layer of optical film 3a and the second layer of optical film 3b respectively. The top and bottom of the second sensing layer 4b is covered with the third layer of optical film 3c and the fourth layer of optical film 3d respectively. An isolation layer 6a is then placed between the two sensing layers, which are covered with optical films, to insulate the two. Lastly, a layer of passivation film 5 is covered on the touch panel circuits to protect them from damages when combining the panel with the display panel. The functions and production process of each layer are similar to those of the embodiments mentioned above and as such, are not repeated here.

Please refer to the twentieth drawing (FIG. 20). FIG. 20 shows the cross section view of the fourth embodiment of the present invention. As shown in the drawing, the fourth embodiment is generally similar to the third embodiment except that a layer of shield 7 is stacked on the fourth layer of optical film 3d before the passivation film 5 is stacked on it. The functions and production process of each layer are similar to those of the embodiments mentioned above and as such, are not repeated here.

The twenty-first drawing is a flow chart of the production process for the preferred embodiment of the present invention (PE 1). The flow chart demonstrates the embodiment process of the integrated touch panel as in the first drawing (FIG. 1). Firstly, the temperature of the production environment has to be maintained below 200° C. at all time. A piece of transparent substrate, e.g. a glass substrate, is cut into a few small pieces (S80). Cutting of the substrate may be carried out with CNC cutters, contour cutters, and laser cutters, etc. Strengthening of the substrates is then carried out by dipping them into chemical solutions like potassium nitrate solutions and so on to increase their strength.

Subsequently, an icon layer is coated on one of the lateral edges of the transparent substrate and the inner periphery of the icon layer is not perpendicular to the adjacent line of the transparent substrate (S82). In order to achieve that, the viscosity of the ink should be within 10˜30 dPa·s, the screen conditioned at 50˜400 mesh tetron screen, and the tension at minimum 15N. The final thickness of the film is around 2˜15 um.

A sensing layer is sputtered on each icon layer and the areas on the transparent substrate that are not coated with icon layer (S84) and its thickness is maintained within 10-100 nm. The sensing layer uses the transparent ITO as its conductance, and due to its nature, the ITO is also an electrode. The process may also be carried out using vacuum DC, RF magnetron sputtering deposition, and other sputtering methods like co-sputtering, layer-by-layer sputtering, spray pyrolysis, pulsed laser deposition, arc discharge ion plating, reactive evaporation, ion beam sputtering, or CVD etc.

In order to prevent the formation of uneven metal slots caused by circuit etching on the sensing layer and to minimize the impairment of visual quality by these uneven slots, a layer of optical film may be stacked before and/or after the sensing layer sputtering is done on the icon layers and areas on the transparent substrate not coated with icon layer. The optical film should be placed on one lateral edge or two lateral edges of the sensing layer (S83) (S85).

Overall, the present invention avoids the conventional method of laminating the substrate and the sensing layers with optically clear adhesive. Instead, the inner edge of the icon layer is not perpendicular to the adjacent line of the transparent substrate so that complete cladding can be obtained when sputtering the optical film or sensing layers on it. This overcomes the unevenness produced when the black icon layer is printed prior to film coating. The yield of the overall structure is thus raised. Furthermore, the quality of the ink used in film-coating the icon layer will not deteriorate and so the resistive value of the ITO sensing layer will not alter. Meanwhile, one layer or two layers of optical film are stacked on the top and/or bottom of each sensing layer to shield any metal slots caused by circuit etching. This will prevent the reduction of resolution and the impairment of visual quality.

All the above-mentioned are only applicable to the preferred embodiment of the present embodiment and will not restrict the scope of the actual embodiment of the present invention. As such, all equivalent or slightly modified versions produced by those familiar with the technology mentioned here will be considered the patent claim of the present invention in the event that such modification is found to be consistent with the essence and claims of the present invention.

What is claimed is:

1. An integrated touch panel comprising:
a transparent substrate;
one of an icon or artwork layer coated on the periphery of one side face of the transparent substrate, and the inner periphery of the icon layer or artwork layer and the adjacent line of the transparent substrate being in a non-perpendicular arrangement;
a first layer of optical film stacked on the icon layer or artwork layer and the areas on the transparent substrate uncovered with the icon layer or artwork layer; and
a first sensing layer stacked on the first layer of optical film by sputtering.

2. The integrated touch panel as cited in claim 1, wherein the transparent substrate is made of one selected from glass and polymer plastic.

3. The integrated touch panel as cited in claim 2, further comprising a second layer of optical film stacked on the first sensing layer.

4. The integrated touch panel as cited in claim 3, further comprising a layer of passivation film stacked on the second layer of optical film.

5. The integrated touch panel as cited in claim 3, further comprising a first isolation layer stacked on the second layer of optical film.

6. The integrated touch panel as cited in claim 5, further comprising a third layer of optical film stacked on the first isolation layer, and a second sensing layer stacked on the third layer of optical film.

7. The integrated touch panel as cited in claim 6, further comprising a layer of passivation film stacked on the second sensing layer.

8. The integrated touch panel as cited in claim 6, further comprising a layer of shield stacked on the second sensing layer.

9. The integrated touch panel as cited in claim 8, further comprising a layer of passivation film stacked on the layer of shield.

10. The integrated touch panel as cited in claim 5, further comprising a second sensing layer stacked on the first isolation layer and a layer of passivation film stacked on the second sensing layer.

11. The integrated touch panel as cited in claim 5, further comprising a second sensing layer stacked on the first isolation layer, a second isolation layer stacked on the second sensing layer, and a layer of shield stacked on the second isolation layer.

12. The integrated touch panel as cited in claim 11, further comprising a layer of passivation film stacked on the layer of shield.

13. The integrated touch panel as cited in claim 2, further comprising a layer of passivation film stacked on the first sensing layer.

14. An integrated touch panel comprising:
a transparent substrate;
one of an icon or artwork layer coated on the periphery of one side face of the transparent substrate, the inner periphery of the icon layer or artwork layer and the adjacent line of the transparent substrate being in non-perpendicular arrangement;
a first sensing layer stacked on the icon layer, and the areas on the transparent substrate uncovered with icon layer; and
a first layer of optical film stacked on the first sensing layer by sputtering.

15. The integrated touch panel as cited in claim 14, further comprising a layer of passivation film stacked on the first layer of optical film.

16. The integrated touch panel as cited in claim 14, further comprising:
a first isolation layer stacked on the first layer of optical film;
a second sensing layer stacked on the first isolation layer: and
a second layer of optical film stacked on the second sensing layer.

17. The integrated touch panel as cited in claim 16, further comprising a layer of passivation film stacked on the second optical film.

18. The integrated touch panel as cited in claim 16, further comprising:
a second isolation layer stacked on the second optical film; and
a layer of shield stacked on the second isolation layer.

19. The integrated touch panel as cited in claim 18, further comprising a layer of passivation film stacked on the shield.

20. An integrated touch panel comprising:
a transparent substrate;
one of an icon or artwork layer coated on the periphery of one side face of the transparent substrate, the inner periphery of the icon layer or artwork layer and the adjacent line of the transparent substrate being in a non-perpendicular arrangement;
a first layer of optical film stacked on the icon layer and the areas on the transparent substrate uncovered with the icon layer;
a first sensing layer stacked on the first layer of optical film by sputtering;
a second optical film stacked on the first sensing layer;
a first isolation layer stacked on the second layer of optical film;
a third layer of optical film stacked on the first isolation layer;
a second sensing layer stacked on the third optical film via sputtering method;
a fourth layer of optical film stacked on the second sensing layer; and
a layer of passivation film stacked on the fourth layer of optical film.

21. An integrated touch panel comprising:
a transparent substrate;
one of an icon or artwork layer coated on the periphery of one side face of the transparent substrate, the inner periphery of the icon layer or artwork layer and the adjacent line of the transparent substrate being in a non-perpendicular arrangement;
a first layer of optical film stacked on the icon layer and the areas on the transparent substrate which are not coated with the icon layer or artwork layer;
a first sensing layer stacked on the first layer of optical film via sputtering method;
a second layer of optical film stacked on the first sensing layer;
a first isolation layer stacked on the second layer of optical film;
a third layer of optical film stacked on the first isolation layer;
a second sensing layer stacked on the third layer of optical film via sputtering method;
a fourth layer of optical film stacked on the second sensing layer; and
a layer of passivation film stacked on the shield.

22. A manufacturing method for an integrated touch panel, the integrated touch panel comprising a transparent substrate, one of an icon or artwork layer coated on the periphery of one side face of the transparent substrate, the inner periphery of the icon layer or artwork layer and the adjacent line of the transparent substrate being in a non-perpendicular arrangement, a first layer of optical film stacked on the icon layer or artwork layer and the areas on the transparent substrate uncovered with the icon layer or artwork layer, and a first sensing layer stacked on the first layer of optical film by sputtering, the temperature being controlled below 200° C. during the entire process, the method comprising steps of:
cutting to form a plurality of transparent substrates;
coating icon layers or artwork layers on the peripheries of side faces of the transparent substrate, arranging the inner periphery of each of the icon layer or artwork layer and the adjacent line of the transparent substrates being in an non-perpendicular arrangement; and
sputtering a sensing layer on each of the icon layers or artwork layers and the areas on the transparent substrate uncovered with the icon layers.

23. The manufacturing method for the integrated touch panel as cited in claim 22, further comprising forming at least one optical film so that the optical film is disposed on one side face or two side faces of the sensing layer before and/or after the step of sputtering the sensing layer on each of the icon layers or artwork layers and the area on the transparent substrate uncovered with the icon layers or artwork layers.
